(19) United States
(12) Patent Application Publication
(10) Pub. No.: US 2026/0126487 A1
(43) Pub. Date: May 7, 2026

(54) Advanced Complex Impedance Matching Capabilities for On–Wafer Antenna Transceiver Measurements

(71) Applicant: FormFactor, Inc., Livermore, CA (US)

(72) Inventors: Pratik Bakul Ghate, Beaverton, OR (US); Ryan Garrison, Hood River, OR (US); Jiexia Shi, Portland, OR (US)

(21) Appl. No.: 19/376,370

(22) Filed: Oct. 31, 2025

Related U.S. Application Data
(60) Provisional application No. 63/715,257, filed on Nov. 1, 2024.

(51) Int. Cl. G01R 31/319; G01R 31/28

(52) U.S. Cl. CPC G01R 31/31914; G01R 31/2812; G01R 31/31905

(57) ABSTRACT

Improved probing of devices under test that have an impedance mismatch to the test equipment is provided. The probes are connected to the test equipment via a flexible circuit, and the impedance matching is done using lumped elements in the flexible circuit. Such lumped elements can be integral to transmission lines in the flexible circuit.

### CROSS REFERENCE TO RELATED APPLICATIONS

This application claims priority from U.S. Provisional Patent Application 63/715257 filed Nov. 1, 2024, which is incorporated herein by reference.

### GOVERNMENT SPONSORSHIP

None.

### FIELD OF THE INVENTION

This invention relates to testing electrical devices with probes.

### BACKGROUND

Electrical probing of a device, circuit or wafer under test is often used in manufacturing to identify good and bad devices before subsequent processing. Such probing is often done by making temporary electrical contact between a probe head including an array of probes and a device under test (DUT). As technology evolves, the frequency at which such testing is done tends to increase, which can lead to new problems not previously encountered in testing. One such issue relates to impedance matching.

Impedance matching is essential in RF (radio frequency) circuit design to maximize power transfer and minimize signal reflections between components. Most RF systems are built around 50Ω impedance due to optimized power transfer and low loss characteristics. However, non-50Ω transmission lines to antennas can provide design advantages including simplified external circuitry requirements and improved antenna efficiency making them subjects of research for use in mixed impedance circuits.

Testing of such components thus raises the issue of how to deal with an impedance mismatch between the test equipment (which will be at 50Ω impedance) and a device under test that may have a substantially different impedance. In contrast, conventional probing of RF devices under test doesn't raise that issue because both the test equipment and the DUT are designed to have 50Ω impedance.

### SUMMARY

This work presents complex impedance matching structures embedded in flexible circuit probe head that will play a major role in improving wafer test coverage with better yield and lower cost of ownership (COO) as immediate benefits.

Impedance matching is defined as the process of equating the input (source) impedance to the output (load) impedance. The power-transfer theorem states that to transfer the maximum amount of power from source to load, the load impedance should match the source impedance. Serious problems such as losses in transmission line increase due to the signal reflections caused by mismatched impedances. Complex impedance (R±jX) includes resistance (the real part of a resistor which dissipates active power (heat), whereas the imaginary part includes inductive reactance or capacitive reactance or both which is frequency dependent and is responsible for the reactive power in the circuit).

The analysis of nonuniform transmission lines has been a subject of interest for a considerable period. One of the uses for such nonuniform lines is in the matching of non-equal impedances over a broadband frequency e.g. 10 MHz to 67 GHz. Most RF systems are built around 50Ω impedance, while some systems use 75Ω; this value is more appropriate in some cases for high-speed digital signals. As the frequency of operation and bandwidths increase, this drives system miniaturization. One consequence being that the antenna is no longer a separate component within the wireless device, but rather is integrated into the device's package. This introduces the concept of antenna-on-chip (AoC) and antenna-in-package (AiP).

These AoC and AiP solutions are studied for highly integrated millimeter-wave (mmWave) devices in wireless communications. For efficient radiation at higher frequencies, antenna impedance is lower than 50Ω impedance. This reason leads to AoC and AiP technologies with non-50Ω and/or complex impedances. To improve the yield of packaged die, we have developed techniques to embed impedance matching structures directly in flexible circuit probe head to reduce multiple impedance transitions between probe card and device under test (DUT) resulting in reduced impedance mismatches.

Customer application has compromised yield because of impedance mismatch between probe card and packaged die due to inefficient test methodologies. Impedance mismatch directly results in loss of dynamic range. This has multiple detrimental consequences including increased insertion loss, reduced signal integrity, additional EM parasitic effects, etc.

With the complex impedance matching capability in flexible circuit probe heads, external impedance matching techniques will be eliminated, making this approach extremely beneficial during test and measurements.

Prior/Current solutions use an external matching technique to match the impedance between the probe and the die on wafer. There are several disadvantages with this approach,
Low Yield and Expensive testing—Presently the test environments include an external impedance transformation technique to match the impedance to the packaged die.

This inefficient technique reduces yield making the entire process expensive.
More time consumption—By using steps of external impedance transformation for testing and evaluation take longer due to inefficiencies in the process, slowing down production cycles.
Possibility of increased mismatch at signal transitions—More number of signal transitions can result in increased impedance mismatch.
Poor control on EM parasitics (capacitance and inductance)—Electromagnetic parasitics, such as capacitance and inductance, are harder to manage with more signal transitions, this negatively impacts performance.
Compromised signal integrity—With poor control on impedance transition through different media signal integrity is compromised.
Higher insertion loss—Insertion loss is directly related to length of transmission line. Reflections and standing waves occur due to impedance mismatch. The higher the impedance mismatch the more reflections leading to signal attenuation i.e. higher insertion loss.

Advantages of the new approach include:
Yield improvements—This approach increases the production yield by increasing the test and measurement quality and reducing the impedance mismatches in a good die.
Lower cost of testing—The new approach will reduce the cost of testing significantly due to eliminating the use of external impedance matching techniques.
Time savings—Without the need to use extra step of external impedance transformation, test times will be reduced significantly leading to cost savings
Less impedance discontinuities—The new method minimizes impedance discontinuities, ensuring smoother signal transitions and improving overall reliability.
Better overall signal integrity—With improved design and control, signal integrity is maintained, reducing data loss and improving system performance.
Better overall performance of the system—The combination of reduced interference, signal loss, and other improvements leads to enhanced system performance.
Impedance matched for the packaged device—The probe card is impedance-matched specifically for the packaged device, optimizing signal transmission and overall functionality.

### BRIEF DESCRIPTION OF THE DRAWINGS

FIGS. 1A-B show examples of flex circuit technology suitable for use in embodiments of the invention.

FIG. 2 schematically shows a probe head suitable for use with embodiments of the invention.

FIG. 3 shows an exemplary flex circuit lumped element impedance matching structure suitable for use in embodiments of the invention.

FIGS. 4A-I show further examples of flex circuit lumped element impedance matching structures.

### DETAILED DESCRIPTION

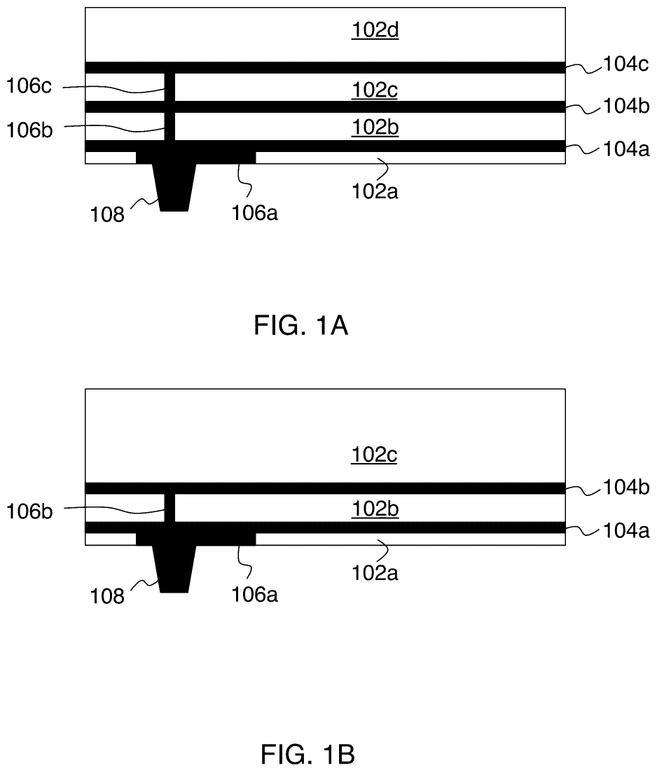

FIGS. 1A-B show examples of flexible circuit technology suitable for use in embodiments of the invention. In general, such technology provides a multi-layer structure of flexible dielectric layers (e.g., 102a, 102b, 102c, 102d on FIG. 1A) and metal layers (e. g., 104 a, 104b, 104c on FIG. 1A). Vertical metal vias (e.g., 106a, 106b, 106c) can be used to make electrical connections between structures separated by the dielectric layers. In the example of FIG. 1A, via 106a connects metal layer 104a to probe tip 108, via 106b connects metal layer 104b to metal layer 104a, and via 106c connects metal layer 104c to metal layer 104b. FIG. 1B is similar to the example of FIG. 1A, except that it has fewer layers. In practice, the metal layers in such flexible circuits can be patterned as traces, transmission lines, or the like, with considerable control over the fabricated shapes. Fabrication of such flexible circuit technology is known in the art, so it is not further described here.

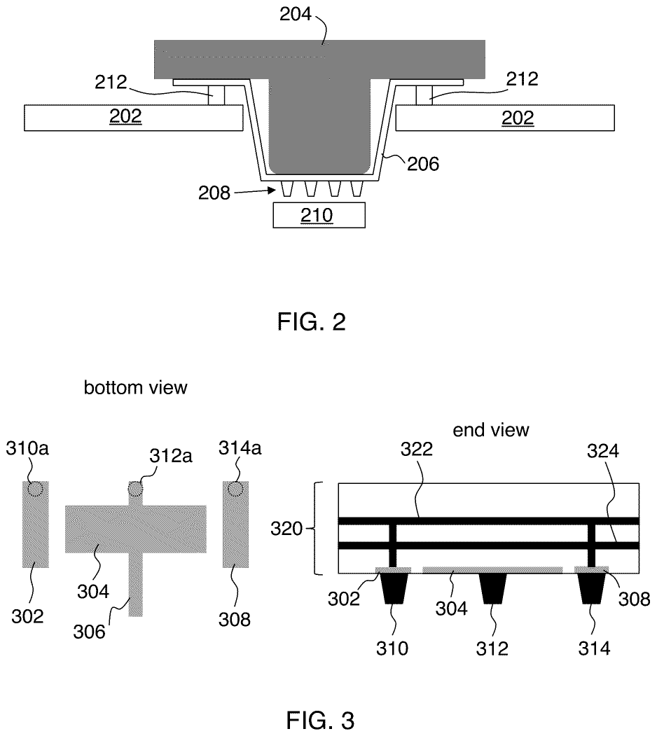

FIG. 2 schematically shows a probe head suitable for use with embodiments of the invention. Here 210 is the device under test, 206 is a flexible circuit as described above, 208 is the array of probe tips, 202 is a substrate (e.g., a printed circuit board (PCB) ), member 204 provides mechanical support for flexible circuit 206 and probe array 208, and 212 schematically shows the core-to-board interface (CBI). Here 204, 206, and 208 are the core of the probe head, and CBI 212 includes the electrical connections between this core and the rest of the probe head (shown schematically here as PCB 202).

As indicated above, the main idea of this work is to add impedance matching structures to flexible circuit 206. More specifically, an exemplary embodiment of the invention is a probe head for making temporary electrical contact to a device under test, where the probe head includes:
an array of probes (e.g., 208 on FIG. 2); and
a flexible circuit (e.g., 206 on FIG. 2) including at least one impedance matching structure (examples described below) configured to provide an impedance match between a test equipment (TE) impedance and a device under test (DUT) impedance.
The array of probes is disposed on the flexible circuit. At least one probe of the probe array is connected to the impedance matching structure such that the probe is configured to probe the device under test at the DUT impedance, and the impedance matching structure includes at least one lumped element.

The TE impedance can be 50Ω or non 50Ω. The DUT impedance is typically not equal to the TE impedance. The TE impedance can be real while the DUT impedance is complex.

Embodiments of the invention are suitable for probing various kinds of device under test, including but not limited to: power amplifiers, filters, optical transceivers, low noise amplifiers, and antennas.

Operation of embodiments of the invention can be at any frequency, although the advantages of the present approach become more significant as frequency increases.

Thus preferred embodiments operate at high frequencies (i.e., 24 GHz or more).

FIG. 3 shows an exemplary flex circuit lumped element impedance matching structure suitable for use in embodiments of the invention. The left part of FIG. 3 is a bottom view and the right part of FIG. 3 is a corresponding end view. Here 306 is a metal trace that is the signal conductor of a transmission line. Metal traces 302 and 308 are corresponding ground traces of the transmission line. 304 is a lumped element impedance matching structure configured as a single rectangle. The end view on the right part of FIG. 3 shows that all of these traces are part of a bottom metal layer of a flexible circuit 320 as described above. Here 312 is the signal probe tip and 310 and 314 are ground probe tips. 310a, 312a, 314a on FIG. 3 (left) show where these probe tips are relative to the metal traces. In this example, the ground probes and ground traces are connected to buried metal layers 322 and 324 in flexible circuit 320, while the signal probe tip 312 is not connected to those buried metal layers.

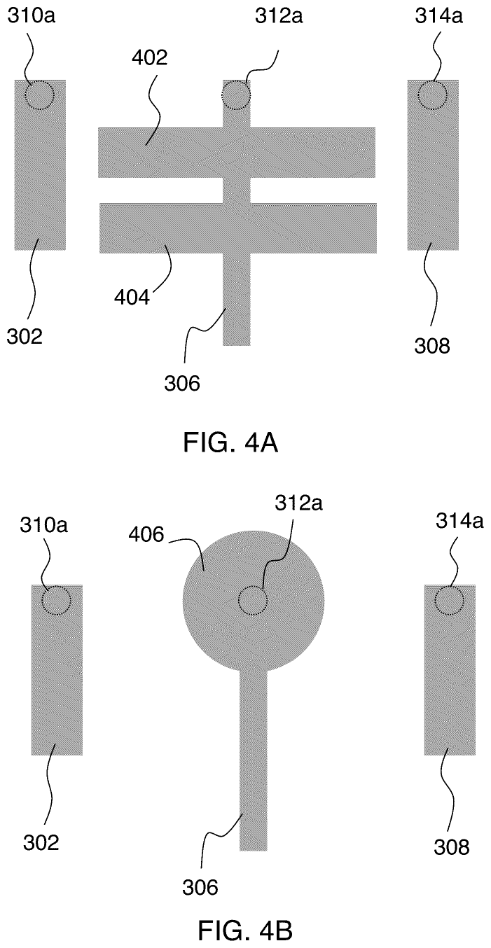

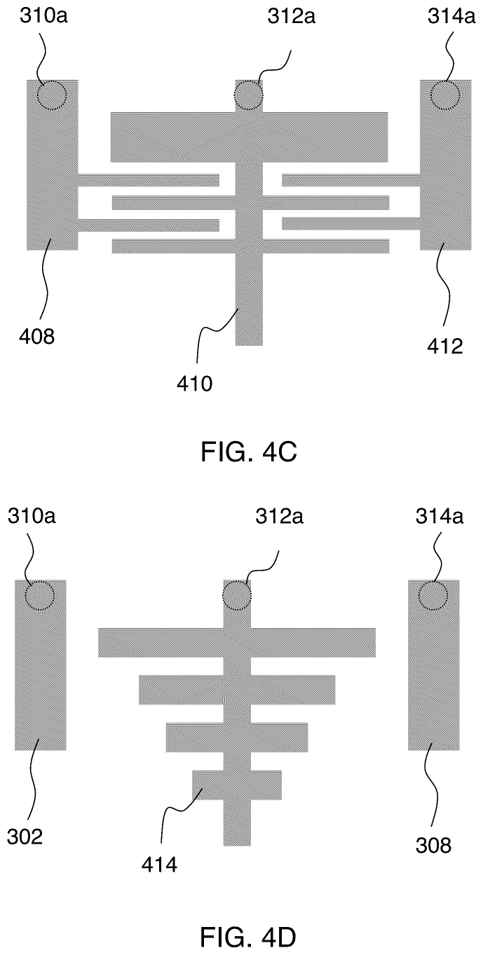

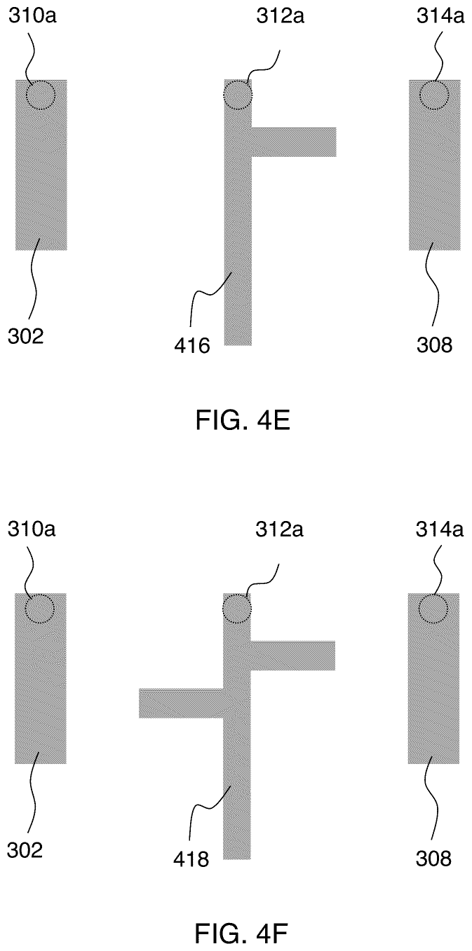

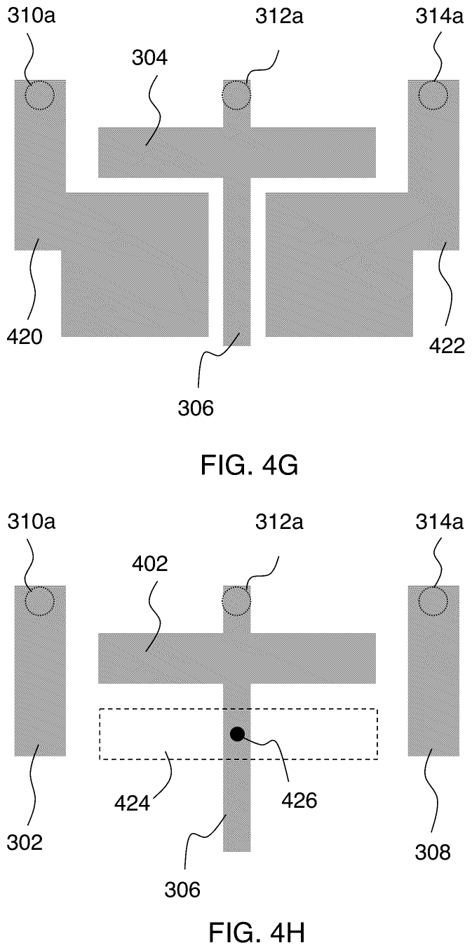

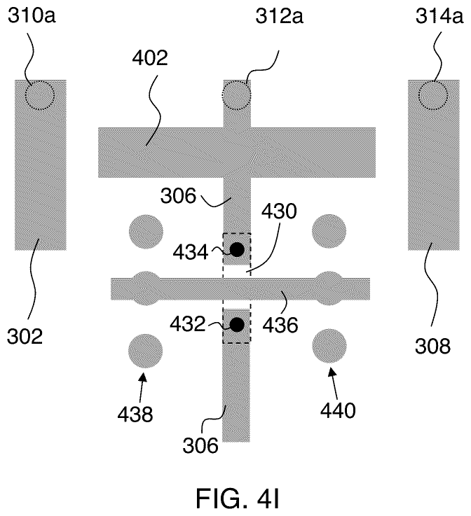

Preferably, the at least one lumped element is integral to a transmission line of the flexible circuit, as in the examples of FIG. 3 and FIGS. 4A-I. The at least one lumped element is preferably configured to provide the impedance match between the test equipment impedance and the device under test impedance.

The lateral distance between a selected one of the at least one lumped element and a base of a corresponding probe of the array of probes is preferably in a range between 0 microns and 100 microns. The example of FIG. 4B below shows an example where this lateral distance is zero for the signal probe.

FIGS. 4A-I show further examples of flex circuit lumped element impedance matching structures. Any lumped element suitable for use in impedance matching can be employed, including but not limited to: single rectangular stepped impedance structures (e.g., FIG. 3), double rectangular stepped impedance structures (e. g., FIG. 4A), circular disk stepped impedance structures (e.g., FIG. 4B), interdigital structures (e.g., FIG. 4C), Yagi-Uda structures (e. g., FIG. 4D), single stub structures (e. g., FIG. 4E), double stub structures (e.g., FIG. 4F), excess ground structures (e.g., FIG. 4G), vertically connected structures (e.g., FIG. 4H), and combinations thereof (e.g., FIG. 4I).

FIG. 4A shows the ground-signal-ground trace pattern for an exemplary double rectangular impedance matching structure including rectangles 402 and 404.

FIG. 4B shows the ground-signal-ground trace pattern for an exemplary circular disk impedance matching structure including disk 406.

FIG. 4C shows the ground-signal-ground trace pattern for an exemplary interdigitated impedance matching structure including a signal trace 410 interdigitated with ground traces 408 and 412.

FIG. 4D shows the ground-signal-ground trace pattern for an exemplary Yagi-Uda matching structure including Yagi-Uda trace 414.

FIG. 4E shows the ground-signal-ground trace pattern for an exemplary single-stub matching structure including single-stub trace 416.

FIG. 4F shows the ground-signal-ground trace pattern for an exemplary double-stub matching structure including double-stub trace 418.

FIG. 4G shows the ground-signal-ground trace pattern for an exemplary excess ground matching structure including excess-ground traces 420 and 422.

FIG. 4H shows the ground-signal-ground trace pattern for an exemplary vertically connected matching structure including buried metal feature 424 connected to signal trace 306 with a vertical via 426.

FIG. 4I shows the ground-signal-ground trace pattern for an exemplary composite matching structure. Here the two parts of trace 306 are connected to each other via buried metal 430 and vias 432 and 434. The impedance matching is provided by rectangle 402 and by coupling of ground strip 436 to buried metal 430. Vias 438 and 440 can induce extra capacitance.

1. A probe head for making temporary electrical contact to a device under test, the probe head comprising:
an array of probes; and
a flexible circuit including at least one impedance matching structure configured to provide an impedance match between a test equipment (TE) impedance and a device under test (DUT) impedance;
wherein the array of probes is disposed on the flexible circuit;
wherein at least one probe of the probe array is connected to the impedance matching structure such that the probe is configured to probe a device under test at the DUT impedance;
wherein the impedance matching structure includes at least one lumped element.

2. The probe head of claim 1, wherein the TE impedance is 50Ω.

3. The probe head of claim 1, wherein the TE impedance is different from 50Ω.

4. The probe head of claim 1, wherein the DUT impedance is not equal to the TE impedance.

5. The probe head of claim 1, wherein the TE impedance is real and the DUT impedance is complex.

6. The probe head of claim 1, wherein the at least one lumped element is integral to a transmission line of the flexible circuit.

7. The probe head of claim 1, wherein the at least one lumped element is configured to provide the impedance match between the TE impedance and the DUT impedance.

8. The probe head of claim 1, wherein a lateral distance between a selected one of the at least one lumped element and a base of a corresponding probe of the array of probes is in a range between 0 microns and 100 microns.

9. The probe head of claim 1, wherein the DUT is selected from the group consisting of: power amplifiers, filters, optical transceivers, low noise amplifiers, and antennas.

10. The probe head of claim 1, wherein the at least one lumped element is selected from the group consisting of: single rectangular stepped impedance structures, double rectangular stepped impedance structures, circular disk stepped impedance structures, interdigital structures, Yagi-Uda structures, single stub structures, double stub structures, excess ground structures, vertically connected structures, and combinations thereof.

11. The probe head of claim 1, wherein an operating frequency of the probe head is 24 GHz or more.

12. The probe head of claim 1, wherein the flexible circuit includes at least one transmission line disposed on or in a thin-film flexible membrane.
